(19) United States
(12) Patent Application Publication
(10) Pub. No.: US 2024/0098925 A1
(43) Pub. Date: Mar. 21, 2024

(54) HOUSING UNIT FOR AN ELECTRONIC COMPONENT OF AN ELECTRICAL REFRIGERANT COMPRESSOR

(71) Applicant: Hanon Systems, Daejeon (KR)

(72) Inventors: Gerald Richter, Aachen (DE); Michael Friedl, Pulheim (DE); Dirk Gutberlet, Würselen (DE); Steffen Koch, Frechen (DE)

(21) Appl. No.: 18/247,693

(22) PCT Filed: Feb. 21, 2022
(86) PCT No.: PCT/KR2022/002540

§ 371 Date: Apr. 3, 2023

(30) Foreign Application Priority Data
Mar. 17, 2021 (DE) 10 2021 106 504.6
Nov. 11, 2021 (DE) 10 2021 129 376.6

(51) Int. Cl. H05K 7/14; H02M 7/00; H05K 5/02; H05K 5/06; H05K 9/00

(52) U.S. Cl. CPC H05K 7/1432; H02M 7/003; H05K 5/0247; H05K 5/06; H05K 9/0045; B60H 2001/3292

(57) ABSTRACT

A housing unit for an electronic component, in particular for an inverter of an electrical refrigerant compressor, wherein the housing unit includes a first housing element and a second housing element, which can be connected to a housing part of the refrigerant compressor, in particular to a motor housing of the refrigerant compressor, and in the process form a cavity which accommodates the electronic component, in particular the inverter.

### CROSS REFERENCE TO RELATED PATENT APPLICATIONS

This is a U.S. national phase patent application of PCT/KR2022/002540 filed Feb. 21, 2022 which claims the benefit of and priority to German Patent Application No. 10 2021 129 376.6 filed on Nov. 11, 2021 and German Patent Application No. 10 2021 106 504.6 filed on Mar. 17, 2021, the entire contents of each of which are incorporated herein by reference.

### TECHNICAL FIELD

The invention relates to a housing unit for an electronic component, in particular for an inverter of an electrical refrigerant compressor. The housing unit is provided for assembly with a housing part, in particular a motor housing part of an electrical refrigerant compressor.

### BACKGROUND ART

A refrigerant compressor is used to compress a gaseous refrigerant in the circuit of an air-conditioning system. In an electrical refrigerant compressor, the compressor unit, which in the case of a scroll compressor consists for example of a stationary scroll and an orbiting scroll, is driven by a drive unit with an electric motor. The electrical drive unit comprises an electronic control unit, the so-called inverter, which is provided to control the electric motor. To connect the inverter region—a housing arrangement in which the inverter is accommodated—various housing configurations are known. Generally, the inverter is accommodated in a support, which allows a thermal connection to remove heat from the electronic components of the inverter. The support is either an integral part of a motor housing of the electrical refrigerant compressor or is flanged to the motor housing as a separate housing constituent. The separate housing constituent consists of the support and a cover, which are mounted on the motor housing together. In the assembled state, the support and the cover form a closed housing for the electronic components of the inverter. The cover is connected to the support by means of a separate seal element for protection from the ingress of moisture, dust and dirt and screw-fastened.

The inverter is electrically contacted to a vehicle system via one or more plug-connectors. Usually, the plug-connector housings and the plug-connectors with electrical conductor contacts are inserted into openings provided in the housing and screw-fastened. Seals are provided between the plug-connector and the housing wall to prevent dust and moisture penetrating into the inverter or between the plug-connector and the housing. Sealing in particular helps to prevent corrosion of the housing parts.

A further essential aspect for the operation of an electrical refrigerant compressor is electromagnetic compatibility (EMC), which is achieved by an appropriate electromagnetic shielding of the electronic components of the electrical refrigerant compressor. As is known, this is achieved by the use of metallic, usually aluminum, housings or housing parts.

A disadvantage of the known housing designs is the required number of individual parts which must be put together in a time-consuming manner during assembly. For instance, multiple screws and a separate seal element are needed to install the plug-connector. These delicate constituents of the plug-connector housing are difficult to handle and demand increased assembly effort. The cover is likewise installed using multiple screws and a seal element to be inserted separately. Furthermore, the machining of openings, plug-connector seats and sealing faces requires considerable manufacturing effort. To ensure adequate corrosion protection, high-quality aluminum alloys are necessary. Seals must be designed such that no liquids can penetrate into gaps. Aluminum covers in the current form of cast parts have additional disadvantages in terms of weight.

### SUMMARY

The object of the invention consists in proposing a housing unit for an electronic component, in particular for an inverter of an electrical refrigerant compressor, which meets the requirements for good electromagnetic compatibility, has a low weight, and can be assembled with little effort.

The object is achieved by a housing unit having the features as shown and described herein.

A housing unit for an electronic component, in particular for an inverter of an electrical refrigerant compressor, is proposed. The housing unit comprises a first housing element and a second housing element, which can be connected to a housing part of the refrigerant compressor, in particular to a motor housing of the refrigerant compressor, and in the process form a cavity which accommodates the electronic component, in particular the inverter.

The cavity is formed by the housing elements when the housing unit is in the assembled state. Accordingly, the housing unit has a cavity in the interior when in the assembled state. To this end, a moulding can be formed on the first housing element and/or on the second housing element, the moulding(s) forming the cavity. The moulding forming the cavity is designed to accommodate the electronic component such that the electronic component is surrounded by the housing unit in a completely enclosed manner when the housing unit is in the assembled state. Furthermore, the housing unit has at least one plug-connector housing integrally moulded on the outside thereof, said plug-connector housing having electrical contact elements for electrically contacting the electronic component accommodated in the cavity. The plug-connector housings are in this case formed as an integral constituent of the housing unit, preferably from the material of the housing unit.

Within the meaning of the invention, an electronic component means in particular an inverter for controlling a motor of an electrical refrigerant compressor. However, other electronic components of the electrical refrigerant compressor can also be accommodated in the housing unit according to the invention.

The housing elements of the housing unit are preferably formed from plastic.

For dust-tight and fluid-tight sealing, seal elements or a sealing material are arranged between the housing elements and the housing part of the refrigerant compressor. The seal elements or the sealing material are arranged between the housing elements and between the housing part of the refrigerant compressor and the housing element, facing the housing part of the refrigerant compressor, of the housing unit according to the invention. Seal elements or the sealing material are thus arranged between all the housing elements of the housing unit that can be assembled.

A further constituent of the housing unit according to the invention is an electromagnetic shielding for the electronic component accommodated in the cavity of the housing unit. The electromagnetic shielding with electrically conductive elements ensures good electromagnetic compatibility.

An advantage of the invention is that a separate support is not needed to accommodate the electronic component, in particular the inverter, since the electronic component is accommodated in the cavity formed by the housing elements. The moulding forming the cavity meets all the requirements to ensure precisely fitting accommodation of the electronic component. A further advantage is the integrally moulded plug-connector housing with the electrical contact elements for electrically contacting the electronic component accommodated in the interior, i.e. in the cavity formed by the housing elements. Because the plug-connector housing is integrally formed from the material of the housing unit, time-consuming assembly of a separate plug-connector housing and the electrical contact elements is no longer necessary. With the integrally moulded plug-connector housing, a separate seal is advantageously no longer necessary, since the at least one plug-connector housing is moulded as a single piece from the material of the housing unit, i.e. as a single piece from the material of the first housing element and/or as a single piece from the material of the second housing element. The electrical contact elements and the electrical conductor contacts for electrically contacting the electronic component can already be provided as inserts during manufacturing of the housing elements, in particular in the case of housing elements produced using injection-moulding, said inserts then being enclosed by the material of the housing unit or of the housing elements and integrated in the process. Such electrical through-connections can be formed on each housing element of the housing unit. The at least one plug-connector housing is designed to accommodate an electrical plug-connector for electrically contacting the electronic component accommodated in the cavity of the housing unit.

According to an advantageous embodiment of the housing unit according to the invention, the at least two housing elements can be formed from electrically conductive plastic, wherein the housing elements consisting of electrically conductive plastic form the electromagnetic shielding of the electronic component accommodated in the interior of the housing unit. In this embodiment, the electromagnetic shielding is advantageously integrated in the housing elements.

It can also be provided for the electromagnetic shielding of the electronic component accommodated in the cavity of the housing unit to be arranged around the electronic component using an overmoulded metal insert, preferably consisting of aluminum, or as a planar or lattice-like element. Advantageously, metal inserts are integrated in the housing elements and therefore do not have to be installed separately. Electrical contacts are formed between the housing elements to allow electrical contacting of the metal inserts of the housing elements.

The electromagnetic shielding of the electronic component accommodated in the cavity in the interior of the housing unit can alternatively or additionally also be applied to the housing elements as an electrically conductive surface coating in the form of a vapor-deposited metal or as a paint.

According to an advantageous development of the housing unit according to the invention, a hole can be provided on the side of the housing unit facing the housing part of the refrigerant compressor, said hole allowing contact between the electronic component accommodated in the cavity of the housing unit and the housing part of the refrigerant compressor. Owing to the hole in the housing unit, contact of the electronic component to the motor housing, usually formed from metal, of the electrical refrigerant compressor is advantageously ensured, and therefore electrical switching elements of a printed circuit board which must be cooled, for example MOSFETs, can be positioned on the motor housing. The motor housing can thus be used as a heat sink to dissipate heat. In the region of the hole in the housing unit, the motor housing can have a flat region on which the electrical components can be arranged to dissipate heat using a large contact area. The hole can be formed in the first housing element or in the second housing element, depending on which housing element faces the housing part of the refrigerant compressor in a preferred arrangement. Thanks to the refrigerant mass flow occurring during compressor operation, the flat region is cooled from the inside, and the inverter or the electrical switching elements are cooled via the housing wall of the motor housing. It is also conceivable for the motor housing to have, in the region of the cutout in the housing unit, a deeper moulding in which electrical switching elements can be positioned with a greater contact area for heat transfer. The efficiency of the heat transfer is advantageously increased thereby.

The housing elements can be connected to one another and/or to the housing part of the electrical refrigerant compressor by screw-fastening, by means of a latch connection or by welding.

A rubber, a plastic or a plastic foam can be used as the sealing material. The sealing material can be attached fixedly to the housing elements by adhesive bonding or using an injection-moulding method. The sealing material is advantageously formed as an integral constituent on the housing elements. This simplifies the assembly of the housing unit, since the sealing material does not have to be positioned separately.

The sealing material can furthermore be a 2-component plastic having an elastic plastic component. Such a 2-component plastic can be applied using an injection-moulding method in which an elastic component forming the seal is injection-moulded on a housing element. The first housing element and the second housing element can thus have injection-moulded seals.

According to a further embodiment of the housing unit according to the invention, it can be provided for the sealing material between the housing elements to be a melt which is formed from the housing element material during welding of contact faces of the housing elements. This embodiment proves suitable if at least one of the housing elements is formed from a plastic. The sealing material to be melted can be introduced before joining between the first housing element and the second housing element as well as between the first housing element facing the housing part of the electrical refrigerant compressor and the housing part of the electrical refrigerant compressor. Furthermore, the first housing element and the second housing element themselves can be formed from a weldable material, the melt forming a sealing material for sealing the housing elements when the first housing element and the second housing element are joined.

Advantageously, the housing unit can be designed such that the cavity is formed with a moulding formed on the first housing element, wherein the second housing element forms a cover which covers at least the moulding of the first housing element in which the electronic component is accommodated. The first housing element and/or the second housing element can be formed from a plastic or a metal. The second housing element can be a cast part or a punched metal part.

The at least one plug-connector housing with the electrical contact elements for electrically contacting the electronic component accommodated in the cavity can be moulded in the first housing element and/or in the second housing element. The at least one plug-connector housing is moulded as a single piece from the material of the housing unit, i.e. the material of the first housing element and/or the material of the second housing element.

The housing unit according to the invention reduces the necessary number of components to be mounted separately and integrates the functions of the electromagnetic shielding. The inverter region is provided as a separate housing unit and flanged to the motor housing of the electrical refrigerant compressor.

### DESCRIPTION OF DRAWINGS

Further details, features and advantages of embodiments of the invention can be found in the description of exemplary embodiments below with reference to the associated drawings. In the figures:

FIGS. 1A/B: show schematic diagrams of an exemplary embodiment of the housing unit according to the invention a) in the assembled state and b) as an exploded diagram,

FIG. 2: shows a schematic diagram of an exemplary embodiment of a housing element of the housing unit according to the invention, in the form of a support housing element,

FIG. 3: shows a schematic diagram of a further exemplary embodiment of the housing unit according to the invention, and

FIG. 4: shows a schematic diagram of yet another exemplary embodiment of the housing unit according to the invention with integrated electromagnetic shielding and integrated seal elements.

### DESCRIPTION OF AN EMBODIMENT

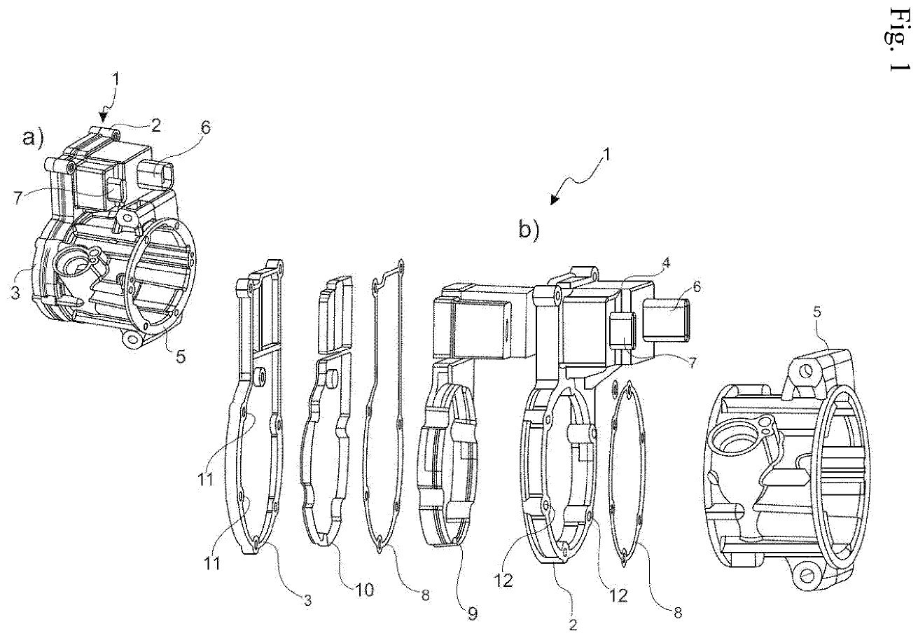

FIG. 1 shows schematic diagrams of an exemplary embodiment of the housing unit according to the invention, in drawing a) in the assembled state and in drawing b) as an exploded diagram. The housing unit 1 has two housing elements 2 and 3 formed from plastic, the first housing element 2 having a moulding 4 for accommodating an inverter (not shown). The first housing element 2 can be referred to as a support housing element. The second housing element 3 forms a cover, which corresponds to the first housing element 2 such that an inverter accommodated in the moulding 4 is fully housed when the housing unit 1 is in the assembled state (see FIG. 1A). The moulding 4 formed on the first housing element 2 together with the second housing element 3 thus forms a cavity of the housing unit 1, in which the inverter is accommodated. The housing parts 2 and 3 can be connected to a motor housing 5 of a refrigerant compressor (not shown). Furthermore, the housing unit 1 has integrally moulded plug-connector housings 6 and 7 on the first housing element 2. The plug-connector housings 6 and 7 are mouldings out of the material of the first housing element 2 for accommodating plug-connectors (not shown). The plug-connector housings 6 and 7 have internal electrical contact elements, via which the inverter accommodated in the cavity can be electrically contacted when corresponding plug-connectors are inserted into the plug-connector housings 6 and 7. The electrical conductors thus extend into the interior of the cavity formed by the first housing element 2 and the second housing element 3. Correspondingly, the electrical contact elements have electrical through-connections for electrical contact with the inverter which is accommodated in the cavity. The plug-connector housing 6 is in the form of a high-voltage terminal, wherein the plug-connector housing 7 is a low-voltage terminal.

Separate seal elements 8 are arranged between the first housing element 2 and the second housing element 3 as well as between the motor housing 5 and the first housing element 2, for dust-tight and fluid-tight sealing.

Furthermore, the housing unit 1 has an electromagnetic shielding for the inverter accommodated in the interior of the housing unit 1 in the cavity. The electromagnetic shielding comprises metal inserts 9 and 10 consisting of aluminum, which are designed such that they are accommodated by the housing elements 2 and 3 and enclose the inverter when the housing elements 2 and 3 are connected to each other. The metal insert 10 is formed in two parts for accommodation in the second housing element 3. The metal insert 9, which corresponds to the inner surface of the first housing element 2 and is accommodated by same, is arranged opposite. When the housing unit 1 is in the assembled state, the metal inserts 9 and 10 form a virtually closed shell around the inverter, as a result of which the electromagnetic shielding is formed. The metal inserts 9 and 10 are thus arranged between the inverter and the housing elements 2 and 3.

The housing elements 2 and 3 are fastened to the motor housing 5 by means of screws (not shown), which are screwed into threads (not shown) of the motor housing 5 through holes 11 formed in the second housing element 3 and corresponding holes 12 formed in the first housing element 2.

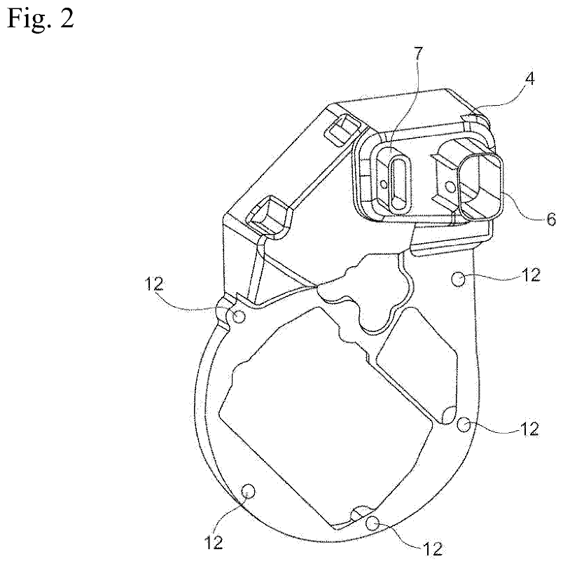

FIG. 2 shows a schematic diagram of an exemplary embodiment of a separate first housing element 2 of the housing unit 1 according to the invention, in the form of a support housing element. The drawing shows a perspective, towards the moulding 4 for accommodating the inverter, of the plug-connector housing 6 in the form of a high-voltage terminal and the plug-connector housing 7 in the form of a low-voltage terminal. The plug-connector housings 6 and 7 are moulded pointing outwards from the material of the first housing element 2. Reference numeral 12 denotes the holes through which screws are passed and screwed into threads of the motor housing 5 in order to fasten the housing unit 1 to the motor housing 5. The electrical contact elements for electrically contacting the inverter are not shown here.

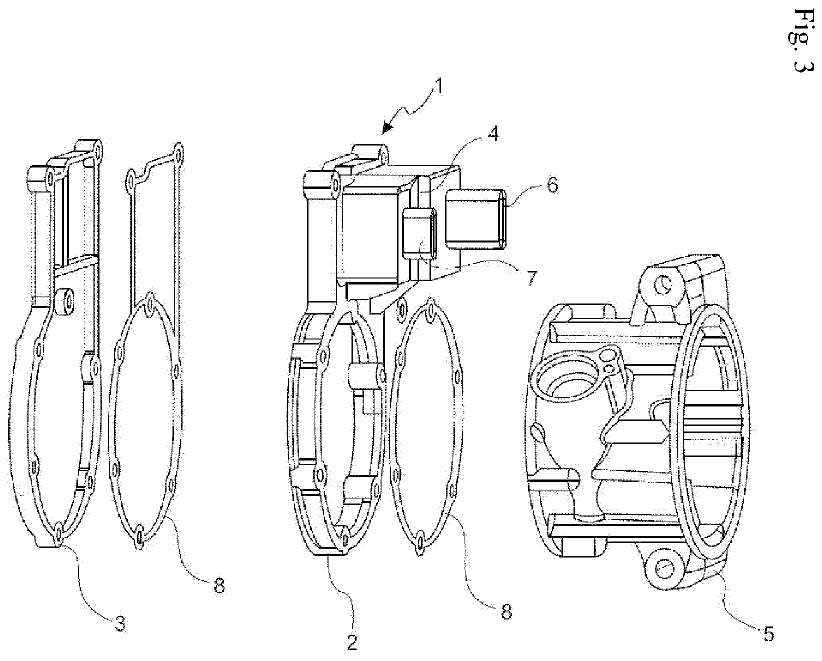

FIG. 3 shows a schematic diagram of a further exemplary embodiment of the housing unit 1 according to the invention with an integrated EMF filter. The embodiment of the housing unit 1 shown in FIG. 3 corresponds substantially to the housing unit 1 shown in FIG. 1B with the difference that the electromagnetic shielding is not in the form of a metal insert. In the embodiment shown in FIG. 3, the electromagnetic shielding is in the form of a metal coating which is deposited on the first housing element 2 and the second housing element 3. The coating can be formed on the inside and/or on the outside. The coating can be applied by a vacuum coating method. It is also possible to apply an electrically conductive coating for electromagnetic shielding to the housing elements 2 and 3 in the form of a paint. Because the electromagnetic shielding is already integrated in the housing elements 2 and 3, the assembly effort can be reduced and the assembly time can be shortened.

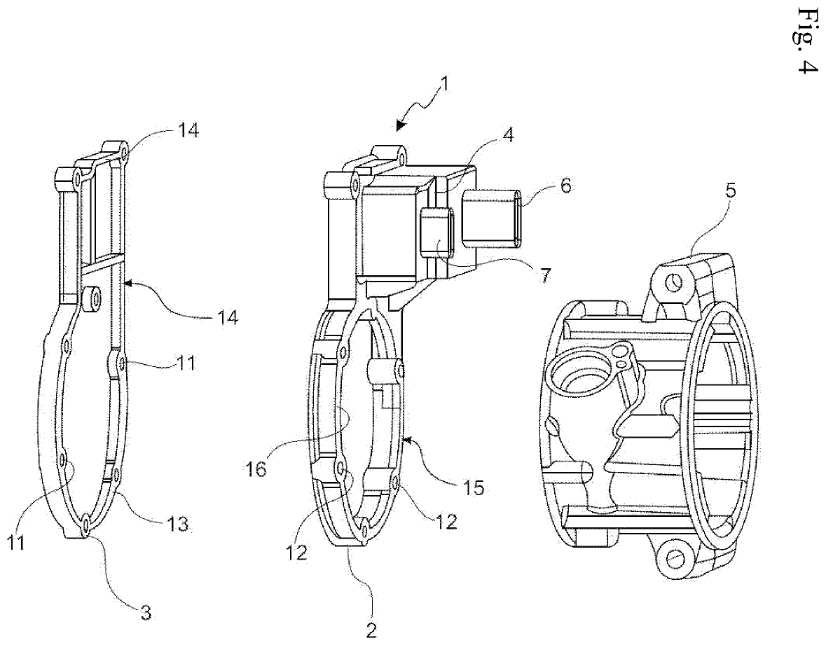

FIG. 4 shows a schematic diagram of yet another exemplary embodiment of the housing unit 1 according to the invention with integrated electromagnetic shielding and integrated seal elements. The embodiment of the housing unit 1 shown in FIG. 4 corresponds substantially to the housing unit 1 shown in FIG. 3 with the difference that the seal elements for sealing the housing elements 2 and 3 and for sealing the entire housing unit 1 against the motor housing 5 are integrated fixedly in the housing elements 2 and 3. In the example shown, an elastic sealing material 13 in the form of a plastic is fastened to the end face 14 of the second housing element 3. The sealing material 13 seals the second housing element 3 against the first housing element 2 when the housing elements 2 and 3 bear against each other in the assembled state.

The first housing element 2 has an end face 15 which faces the motor housing 5. An elastic sealing material 16 in the form of a plastic is likewise fastened to this end face 15 in order to seal the housing unit 1 against the motor housing 5 when in the assembled state. Because the sealing material 13 and the sealing material 16 are formed fixedly on the housing elements 2 and 3, the assembly time can be reduced further, since time-consuming positioning of separate seal elements is no longer necessary. The housing elements 2 and 3 advantageously only have to be put together for assembly.

### LIST OF REFERENCE NUMERALS

1 Housing unit
2 First housing element
3 Second housing element
4 Moulding
5 Housing part of refrigerant compressor, motor housing
6 Plug-connector housing
7 Plug-connector housing
8 Seal element
9 Metal insert
10 Metal insert
11 Hole
12 Hole
13 Sealing material
14 End face
15 End face
16 Sealing material

1-14. (canceled)

15. A housing unit for an electronic component, in particular for an inverter of an electrical refrigerant compressor, wherein the housing unit comprises:
a first housing element and a second housing element, which can be connected to a housing part of the refrigerant compressor, in particular to a motor housing of the refrigerant compressor, and in the process form a cavity which accommodates the electronic component, in particular the inverter, wherein the housing unit further comprises:
at least one plug-connector housing integrally moulded on an outside thereof, the at least one plug-connector housing having electrical contact elements for electrically contacting the electronic component accommodated in the cavity,
seal elements or a sealing material, which is/are arranged between the first housing element and the second housing element and the housing part of the refrigerant compressor for dust-tight and fluid-tight sealing, and
an electromagnetic shielding for the electronic component accommodated in the cavity in an interior of the housing unit.

16. The housing unit according to claim 15, wherein the first housing element and the second housing element are formed from electrically conductive plastic, wherein the first housing element and the second housing element consisting of electrically conductive plastic form the electromagnetic shielding of the electronic component accommodated in the cavity of the housing unit.

17. The housing unit according to claim 15, wherein the electromagnetic shielding of the electronic component accommodated in the cavity of the housing unit is formed using an overmoulded metal insert, preferably consisting of aluminum, or is arranged around the electronic component as a planar or lattice-like element.

18. The housing unit according to claim 15, wherein the electromagnetic shielding of the electronic component accommodated in the cavity of the housing unit is applied to the first housing element and the second housing element as an electrically conductive surface coating in the form of a vapour-deposited metal or as a paint.

19. The housing unit according to claim 15, wherein a hole is formed on a side of the first housing element facing the housing part of the refrigerant compressor, the hole allowing contact between the electronic component accommodated in the cavity of the housing unit and the housing part of the refrigerant compressor.

20. The housing unit according to claim 15, wherein the first housing element and the second housing element are connected to one another and/or to the housing part of the electrical refrigerant compressor by screw-fastening, by a latch connection, or by welding.

21. The housing unit according to claim 15, wherein the sealing material is a rubber, a plastic or a plastic foam, which is attached fixedly to the first housing element and the second housing element by adhesive bonding or by injection-moulding.

22. The housing unit according to claim 15, wherein the sealing material is a 2-component plastic having an elastic plastic component.

23. The housing unit according to claim 15, wherein the sealing material between the first housing element and the second housing element is a melt which is formed from a material forming the first housing element and the second housing element during welding of contact faces of the first housing element and the second housing element.

24. The housing unit according to claim 15, wherein the cavity is formed with a moulding formed on the first housing element, wherein the second housing element forms a cover which covers at least the moulding of the first housing element, in which the electronic component is accommodated.

25. The housing unit according to claim 24, wherein the first housing element and/or the second housing element are formed from a plastic or a metal.

26. The housing unit according to claim 23, wherein the second housing element is a cast part or a punched metal part.

27. The housing unit according to claim 22, wherein the at least one plug-connector housing having the electrical contact elements for electrically contacting the electronic component accommodated in the cavity is moulded on the second housing element and/or on the first housing element.

28. The housing unit according to claim 15, wherein the at least one plug-connector housing is moulded as a single piece from a material forming the housing unit.
